(19) United States
(12) Patent Application Publication
(10) Pub. No.: US 2013/0063911 A1
(43) Pub. Date: Mar. 14, 2013

(54) ELECTRONIC APPARATUS AND CYLINDRICAL BODY

(71) Applicants: Ken SHOJI, Kawasaki (JP); Yoshihiro ONO, Yokohama (JP)

(72) Inventors: Ken SHOJI, Kawasaki (JP); Yoshihiro ONO, Yokohama (JP)

(73) Assignee: FUJITSU LIMITED, Kawasaki-shi (JP)

(21) Appl. No.: 13/541,491

(22) Filed: Jul. 3, 2012

(30) Foreign Application Priority Data
Sep. 8, 2011 (JP) 2011-196553

(51) Int. Cl. H05K 7/16

(52) U.S. Cl. 361/755

(57) ABSTRACT

An electronic apparatus includes: a first housing including a first circuit board; a second housing including a second circuit board, the second housing being openable and closable using a hinge and the first housing; and a cable configured to couple the first circuit board to the second circuit board, wherein the hinge includes: a first hinge case attached to the first housing; a second hinge case attached to the second housing; and a cylindrical body configured to rotatably couple the first hinge case to the second hinge case, the cylindrical body including a hole through which the cable passes.

### CROSS-REFERENCE TO RELATED APPLICATION(S)

This application is based upon and claims the benefit of priority of the prior Japanese Patent Application No.2011-196553, filed on Sep. 8, 2011, the entire contents of which are incorporated herein by reference.

### FIELD

The embodiments discussed herein are related to an electronic apparatus and a cylindrical body.

### BACKGROUND

Inserting a coaxial cable into a ferrite core may reduce noise of an apparatus caused by electromagnetic interference.

A related technique is disclosed in Japanese Laid-open Patent Publication No. 10-116638.

### SUMMARY

According to one aspect of the embodiment, an electronic apparatus includes: a first housing including a first circuit board; a second housing including a second circuit board, the second housing being openable and closable using a hinge and the first housing; and a cable configured to couple the first circuit board to the second circuit board, wherein the hinge includes: a first hinge case attached to the first housing; a second hinge case attached to the second housing; and a cylindrical body configured to rotatably couple the first hinge case to the second hinge case, the cylindrical body including a hole through which the cable passes.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an exemplary electronic apparatus;

FIG. 2 illustrates an exemplary electronic apparatus;

FIG. 3 illustrates an exemplary electronic apparatus of FIG. 2;

FIG. 4 illustrates an exemplary electronic apparatus of FIG. 2;

FIG. 5 illustrates an exemplary electronic apparatus of FIG. 2;

FIG. 6 illustrates an exemplary hinge;

FIG. 7 illustrates an exemplary cylindrical body;

FIG. 8 illustrates an exemplary cylindrical body;

FIG. 9 illustrates an exemplary cylindrical body;

FIG. 10 illustrates an exemplary method for assembling a hinge part; and

FIG. 11 illustrates an exemplary method for assembling a hinge part.

### DESCRIPTION OF EMBODIMENTS

A cable couples a first circuit board and a second circuit board included in a first housing and a second housing, respectively, which are openable and closable on a hinge. Inserting the cable into a thick ferrite core may make it difficult to downsize the electronic apparatus. A part of the cable is stretched and bent by opening and closing of the first housing and the second housing. Attaching a hard ferrite core to this part of the cable may reduce the ability of the electronic apparatus to withstand the opening and closing.

Elements having substantially the same or similar structures are designated by the same reference numerals and their description may be omitted or reduced.

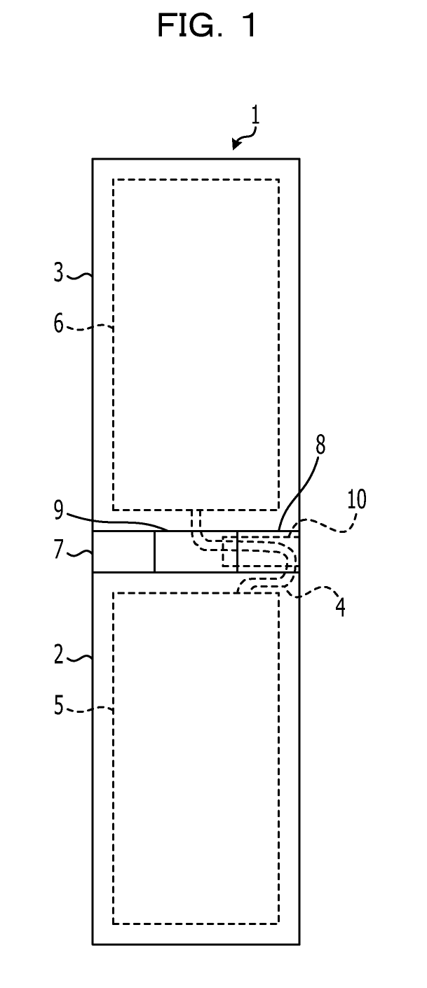

FIG. 1 illustrates an exemplary electronic apparatus. FIG. 1 may be an entire view of the electronic apparatus. An electronic apparatus 1 illustrated in FIG. 1 includes a first housing 2, a second housing 3, and a cable 4. The first housing 2 includes a first circuit board 5. The second housing 3 includes a second circuit board 6. The second housing 3 is openably and closably coupled via a hinge 7 to the first housing 2. The cable 4 couples the first circuit board 5 to the second circuit board 6.

The hinge 7 includes a first hinge case 8, a second hinge case 9, and a cylindrical body 10. The first hinge case 8 is secured to the first housing 2. The second hinge case 9 is secured to the second housing 3. The cylindrical body 10 rotatably couples the first hinge case 8 to the second hinge case 9. The cylindrical body 10 may include a material with high saturation flux density, such as magnetic steel, and may have a hole through which the cable 4 passes.

Inserting the cable 4 into the cylindrical body 10 may allow the magnetic steel, included in the cylindrical body 10, to act in a manner substantially the same as or similar to a ferrite core. The magnetic steel absorbs a magnetic field generated by current flowing through the cable 4, and converts the magnetic field into heat. This may reduce noise radiated from the cable 4. If no ferrite core is attached to the cable 4, the size of the electronic apparatus 1 may be reduced. If no ferrite core is attached to a part of the cable 4 stretched and bent by opening and closing of the first housing 2 and the second housing 3, the ability of the electronic apparatus 1 to withstand the opening and closing may be improved.

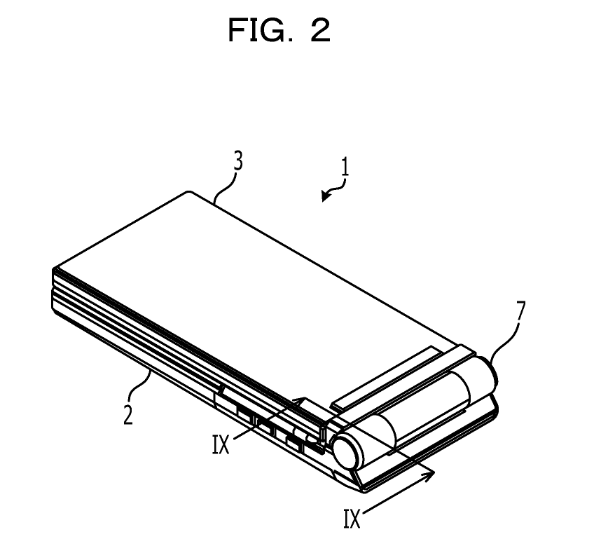

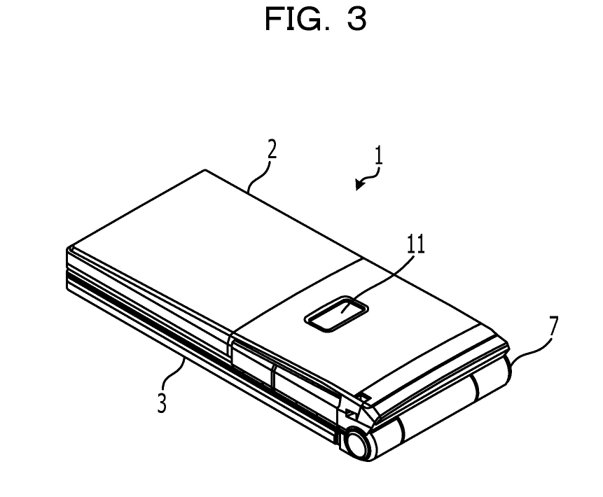

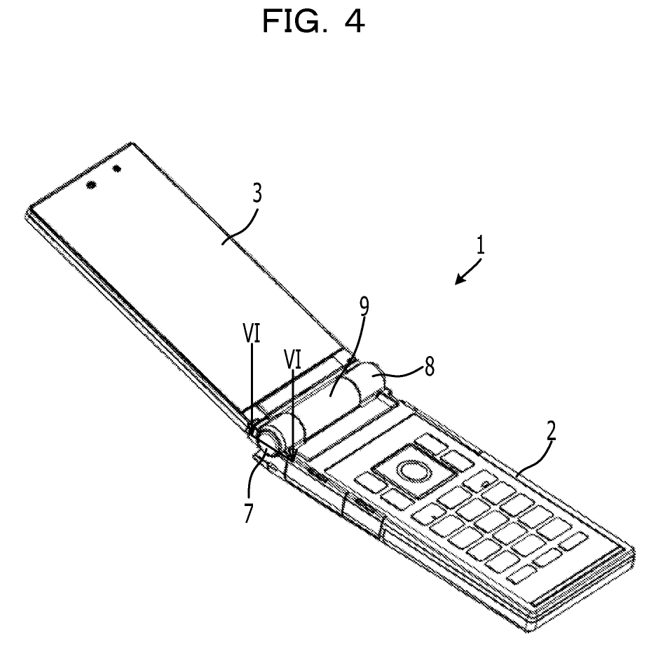

FIG. 2, FIG. 3, and FIG. 4 illustrate an exemplary electronic apparatus. FIG. 2 may be a perspective view illustrating a front side of the electronic apparatus 1. FIG. 3 may be a perspective view illustrating a back side of the electronic apparatus 1. FIG. 4 may be an external perspective view of the electronic apparatus 1, with the first housing 2 and the second housing 3 opened. The electronic apparatus 1 may be, for example, a mobile phone. In the mobile phone, the second housing 3 on the front side and the first housing 2 on the back side are openably and closably attached to each other by the hinge 7.

For example, the second housing 3 may include a display panel. For example, the first housing 2 may include a keypad and may house a battery. A fingerprint sensor unit 11 may be included in the first housing 2.

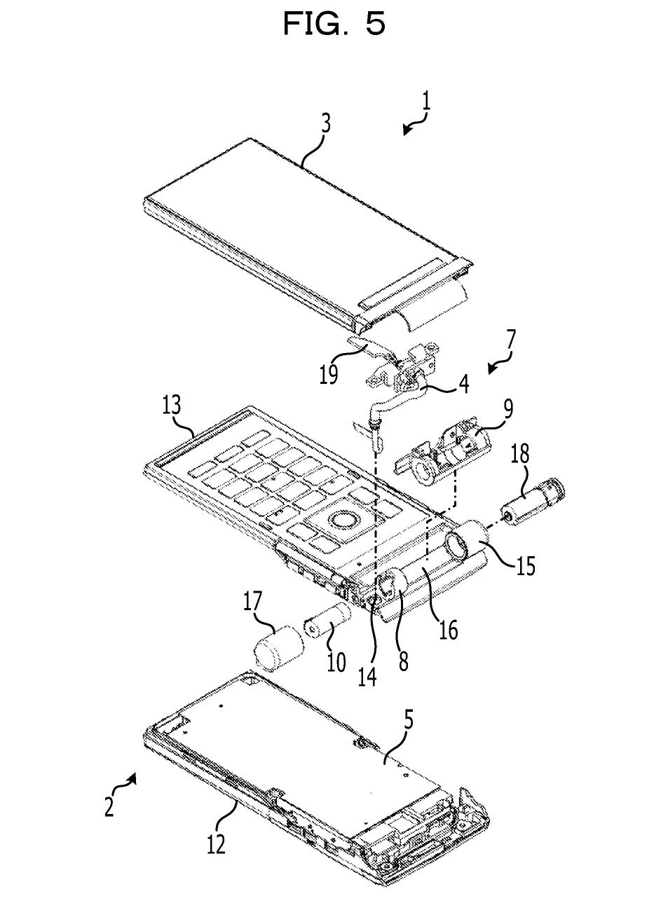

FIG. 5 illustrates an exemplary electronic apparatus. FIG. 5 may be an exploded perspective view of the electronic apparatus 1 of FIG. 2 to FIG. 4. The first housing 2 includes a housing body 12 and a lid 13 that closes the housing body 12. The first circuit board 5 may be housed between the housing body 12 and the lid 13. The lid 13 may include, for example, the keypad.

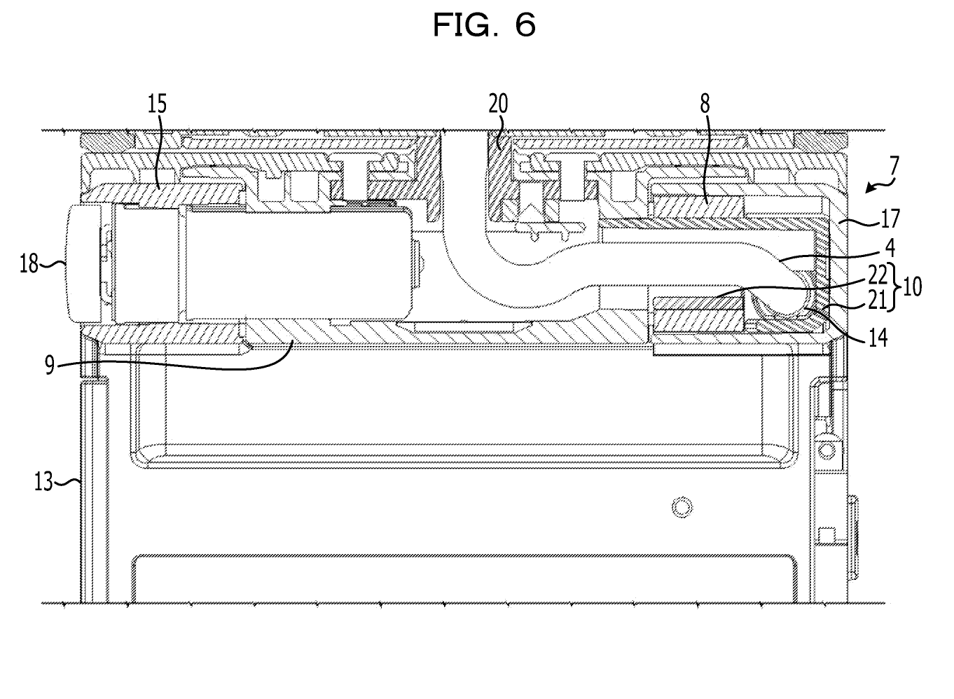

FIG. 6 illustrates an exemplary hinge. FIG. 6 may be a cross section of a hinge part taken parallel to a plane containing operation keys, for example, a cross-sectional view taken along line VI-VI of FIG. 4. As illustrated in FIG. 5 and FIG. 6, the hinge 7 may be divided into, for example, three parts: the first hinge case 8, the second hinge case 9, and a third hinge case 15. In the hinge 7, the first hinge case 8 and the third hinge case 15 are disposed on both ends of the lid 13 of the first housing 2. In the lid 13, the second hinge case 9 is located in a receiving portion 16 between the first hinge case 8 and the third hinge case 15.

The cable 4 extending from the center of the second hinge case 9 is passed through the interior of the first hinge case 8, further passed through a through hole 14 at an end of the lid 13, drawn downward out of the lid 13, and coupled to the first circuit board 5. For convenience, FIG. 6 illustrates an outer appearance, not a cross section, of the cable 4. The cylindrical body 10 is inserted from a first side of the lid 13, through the interior of the first hinge case 8, into the second hinge case 9. The cylindrical body 10 may be referred to as “first cylindrical body 10”. The first hinge case 8 and the first cylindrical body 10 may be covered with an exterior component 17 having an outer appearance substantially the same as or similar to that of, for example, the third hinge case 15.

A second cylindrical body 18 is inserted from a second side of the lid 13, through the interior of the third hinge case 15, into the second hinge case 9. For convenience, FIG. 6 illustrates an outer appearance, not a cross section, of the second cylindrical body 18. The first cylindrical body 10 and the second cylindrical body 18 allow the second hinge case 9 to rotate relative to the first hinge case 8 and the third hinge case 15. The second housing 3 is secured to the second hinge case 9. This allows the second housing 3 to open and close relative to the first housing 2.

A first end of the cable 4 may be provided with a connector 19. The connector 19 extends from the second hinge case 9 to the interior of the second housing 3 and is coupled to the second circuit board 6 (not illustrated in FIG. 5 and FIG. 6) included in the second housing 3.

A rotating hinge 20 may be housed in the second hinge case 9. The rotating hinge 20 includes a cylindrical body having an axis perpendicular to the rotation axis of the first cylindrical body 10 and the second cylindrical body 18. Mounting the rotating hinge 20 allows the second housing 3 to pivot about the rotation axis of the first cylindrical body 10 and the second cylindrical body 18, relative to the first housing 2. Therefore, the second housing 3 remaining open in respect to the first housing 2 rotates about the axis perpendicular to the rotation axis of the first cylindrical body 10 and the second cylindrical body 18. The rotating hinge 20 and the cable 4 may be assembled as an integral component.

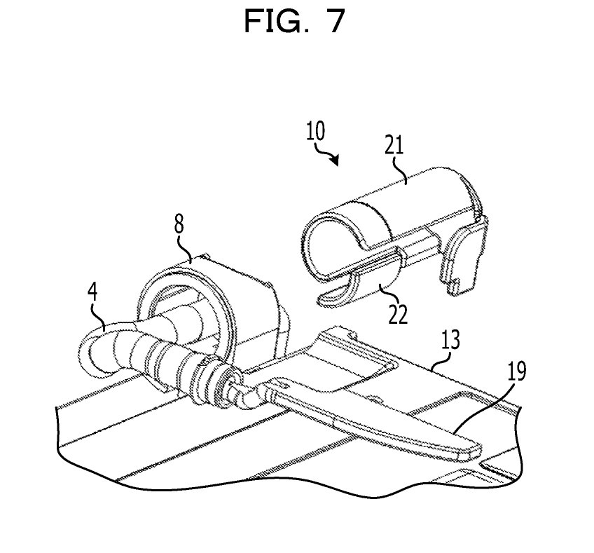

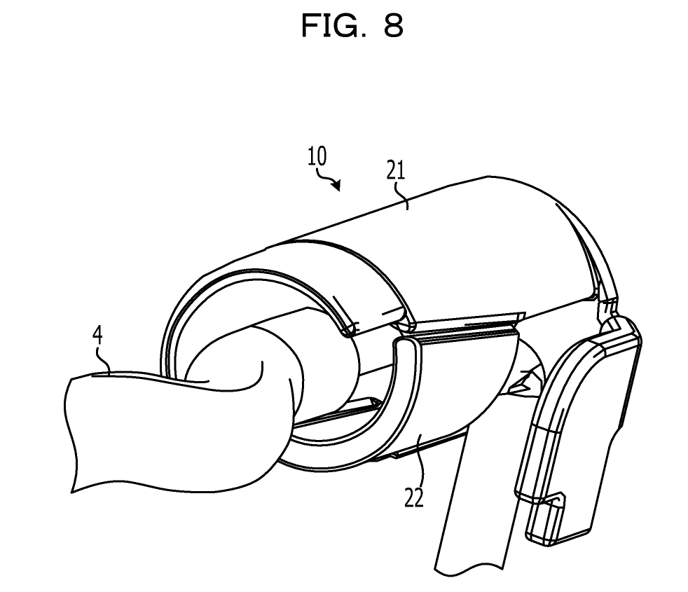

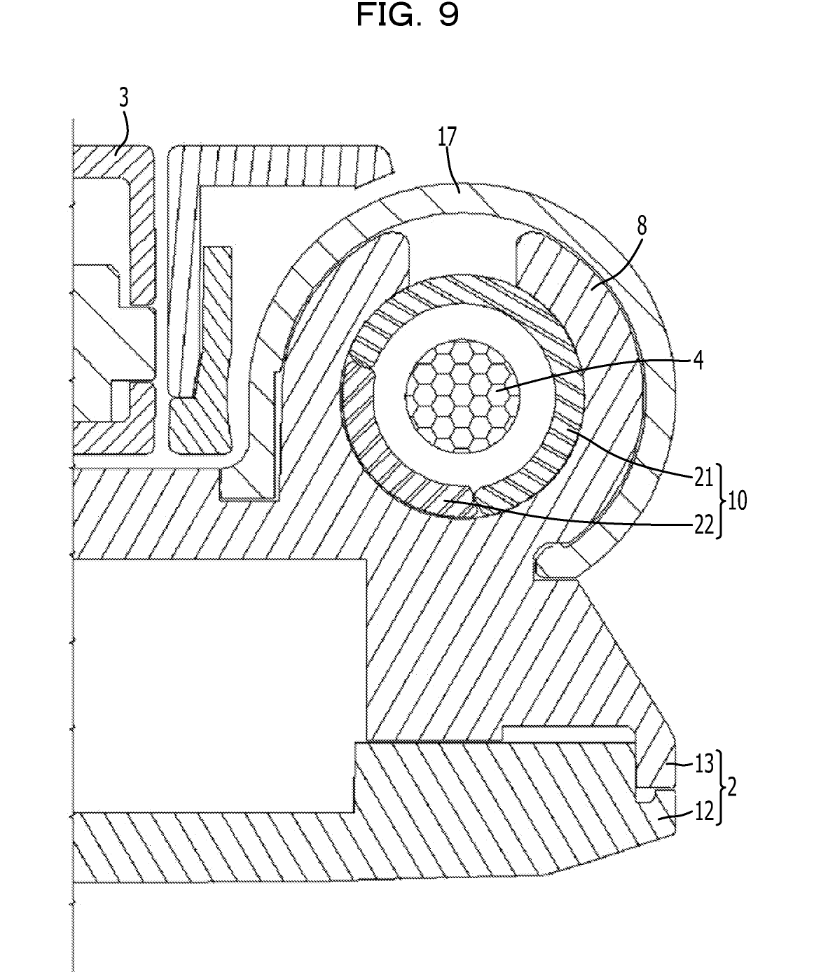

FIG. 7, FIG. 8, and FIG. 9 illustrate a cylindrical body. FIG. 7 may be an exploded perspective view illustrating the first cylindrical body 10 of the electronic apparatus 1. FIG. 8 may be a perspective view illustrating the first cylindrical body 10 of the electronic apparatus 1. FIG. 9 may be a cross-sectional view illustrating the first cylindrical body 10 of the electronic apparatus 1 taken along line IX-IX of FIG. 2. For convenience, the illustration of some elements may be omitted in FIG. 7 to FIG. 9. FIG. 8 illustrates a state of the first cylindrical body 10 and the cable 4 which are placed in the first hinge case 8 (not illustrated) and the second hinge case 9 (not illustrated).

As illustrated in FIG. 7 to FIG. 9, the first cylindrical body 10 includes a main body 21 and a component 22. The main body 21 may be molded into a partially open shape to provide a receiving window for receiving the cable 4. Edges of the main body 21 opened to provide the receiving window are closed by the component 22. Thus, the first cylindrical body 10 having a substantially circular cylindrical portion is created. The cable 4 passes through the substantially circular cylindrical portion of the first cylindrical body 10. In assembling the mobile phone, the cable 4 may be inserted through the receiving window of the main body 21 into the main body 21.

Although the component 22 is placed outside the first hinge case 8 in FIG. 7, the component 22 may be secured to the inner surface of the first hinge case 8 in advance. When the main body 21 is inserted from the first side of the lid 13 into the first hinge case 8, the component 22 may be secured in place to close the edges of the main body 21 opened by the receiving window.

For example, the substantially circular cylindrical portion formed by engagement of the main body 21 and the component 22 may be made of or include magnetic steel. The magnetic steel may be, for example, SUS430L or SUS410L.

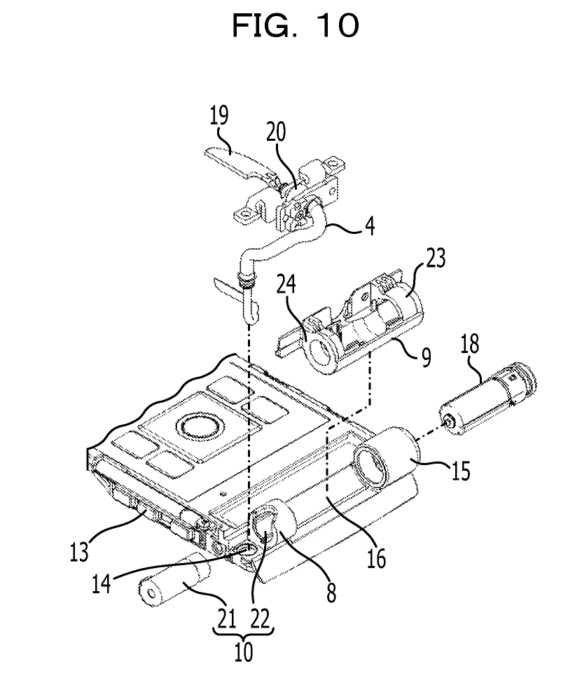

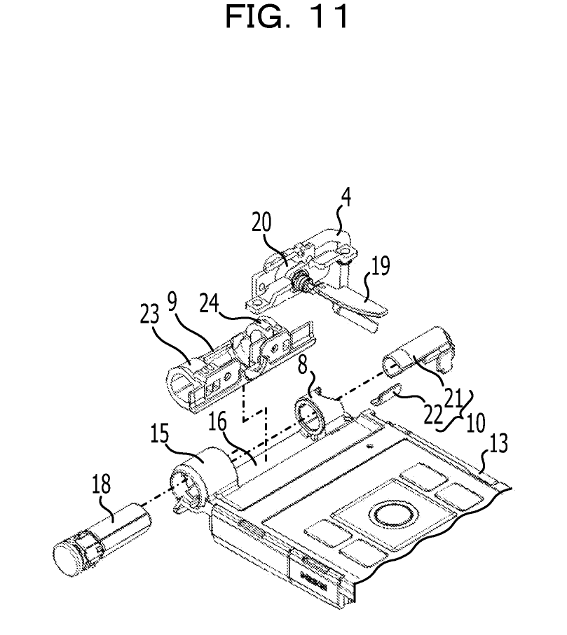

FIG. 10 and FIG. 11 illustrate an exemplary method for assembling a hinge part. FIG. 10 and FIG. 11 may be exploded perspective views of the hinge part. As illustrated in FIG. 10 and FIG. 11, in assembling the hinge part, the second hinge case 9 is placed in the receiving portion 16 of the lid 13. The second cylindrical body 18 is inserted from the second side of the lid 13. An end portion of the second cylindrical body 18 is inserted into a first bearing 23 of the second hinge case 9. Thus, the second hinge case 9 is coupled to the lid 13.

A second end of the cable 4 extending from the center of the second hinge case 9 is passed through the interior of the first hinge case 8. Thus, the rotating hinge 20 is placed inside the second hinge case 9. The second end of the cable 4 passed through the interior of the first hinge case 8 is further passed through the through hole 14 of the lid 13, drawn downward out of the lid 13, and coupled to the first circuit board 5 (not illustrated in FIG. 10 and FIG. 11).

The main body 21 of the first cylindrical body 10 is inserted into the first hinge case 8. An end portion of the main body 21 is inserted into a second bearing 24 of the second hinge case 9. In the interior of the first hinge case 8, the main body 21 and the component 22 made of or including magnetic steel may circular-cylindrically surround the cable 4. The first hinge case 8 is covered with the exterior component 17 (not illustrated in FIG. 10 and FIG. 11). Thus, the assembly of the hinge part of the mobile phone is completed.

The effect of the electronic apparatus illustrated in FIG. 2 to FIG. 11 may be substantially the same as or similar to that of the electronic apparatus illustrated in FIG. 1. Since the effect of noise generated by the cable 4 is reduced, the communication characteristics of the mobile phone may be improved. Also, since the effect of noise generated by the cable 4 is reduced, no ferrite core and no sheet-like component for absorbing or blocking electromagnetic waves may have to be attached to the cable 4. This may reduce the number of worker-hours and cost involved in assembling the mobile phone.

The electronic apparatus 1 may be a mobile phone, a clamshell computer having a hinge, a mobile information terminal such as a personal digital assistant (PDA), a portable video game player, or various measuring devices. The electronic apparatus 1 may be an electronic apparatus that combines the functions of both a mobile phone and a mobile information terminal, such as a smartphone.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic apparatus comprising:
a first housing including a first circuit board;
a second housing including a second circuit board, the second housing being openable and closable using a hinge and the first housing; and
a cable configured to couple the first circuit board to the second circuit board,
wherein the hinge includes:
a first hinge case attached to the first housing;
a second hinge case attached to the second housing; and
a cylindrical body configured to rotatably couple the first hinge case to the second hinge case, the cylindrical body including a hole through which the cable passes.

2. The electronic apparatus according to claim 1,
wherein the cylindrical body includes magnetic steel.

3. The electronic apparatus according to claim 1,
wherein the cylindrical body is inserted into the first hinge case and the second hinge case extending the first hinge case and the second hinge case.

4. The electronic apparatus according to claim 1,
wherein the cylindrical body includes a portion that surrounds the cable and includes magnetic steel.

5. The electronic apparatus according to claim 1,
wherein the cylindrical body includes
a main body partially opened to provide a receiving window for the cable; and
a component configured to close edges of the main body opened by the receiving window.

6. The electronic apparatus according to claim 5,
wherein a portion of the main body and the component which surrounds the cable includes magnetic steel.

7. The electronic apparatus according to claim 5,
wherein the component is provided inside the first hinge case and closes the edge of the main body when the main body is inserted into the first hinge case.

8. A cylindrical body, comprising,
a hole configured to pass through a cable which rotatably couples a first hinge case secured to a first housing to the second hinge case secured to a second housing openable and closable using a hinge and the first housing, and couples a first circuit board in the first housing to a second circuit board in the second housing.

9. The cylindrical body according to claim 8,
wherein the cylindrical body includes magnetic steel.

10. The cylindrical body according to claim 8, further comprising,
a portion configured to surround the cable and include magnetic steel.

11. The cylindrical body according to claim 8, further comprising:
a main body partially opened to provide a receiving window for the cable; and
a component configured to close edges of the main body which is opened by the receiving window.
